(19) United States
(12) Patent Application Publication
(10) Pub. No.: US 2003/0109148 A1
(43) Pub. Date: Jun. 12, 2003

(54) Technique for growing single crystal material on top of an insulator

(75) Inventor: Majeed A. Foad, Sunnyvale, CA (US)

Correspondence Address: APPLIED MATERIALS, INC., Legal Affairs Dept., P.O. Box 450A, Santa Clara, CA, 95054, US

(73) Assignee: APPLIED MATERIALS, INC.

(21) Appl. No.: 10/272,757

(22) Filed: Oct. 17, 2002

Related U.S. Application Data
(60) Provisional application No. 60/348,189, filed on Oct. 18, 2001.

(51) Int. Cl. H01L 21/20; H01L 21/36; H01L 21/42

(52) U.S. Cl. 438/795; 438/799; 438/487

(57) ABSTRACT

A method including introducing over a wafer a material having a crystalline form, identifying a crystal in the material of a desired lattice orientation, and configuring the material to the lattice orientation of the crystal. A system for growing a film on a substrate including a chamber, a laser light source coupled to the chamber and configured to direct a laser light into the chamber, and a processor coupled to the chamber comprising a machine readable medium including executable program instructions that when executed cause the processor to perform a method including identifying a crystal of a desired lattice orientation in a crystalline material introduced over a wafer, and configuring, the material to a lattice orientation of the identified crystal.

### CROSS-REFERENCE TO RELATED APPLICATION

This application claims the benefit of the earlier filing date of copending provisional application Serial No. 60/348,189, filed Oct. 18, 2001, by Majeed A. Foad, titled “Technique for Growing Single Crystal Si on Top of an Insulator”, and incorporated herein by reference.

### FIELD

The invention relates to semiconductor material processing and more particularly to the formation of thin films of crystallized semiconductor material.

### BACKGROUND

Modern integrated circuits are typically formed adjacent (in and/or on) a semiconductor substrate, such as a silicon substrate. Typically, at least many hundreds of devices are integrated surface are formed on a wafer (e.g., an 8-inch diameter substantially circular wafer). After formation of the individual devices or integrated circuits, the wafer is diced to form the discrete devices or integrated circuits.

According to current technology, a silicon wafer has a thickness on the order of about 600-750 microns. The wafer is usually formed from electronic grade polysilicon (EGS) that is used to grow single crystal silicon by Czochralski (CZ) crystal growth or float zone (FZ) growth. The single crystal silicon is typically commercially available in either {100}- or {111}-orientations though other orientations are possible. Steps are taken in either the CZ growth or FZ growth to minimize impurities in the bulk silicon, particularly at the wafer surface. Nevertheless, impurities do exist in the bulk silicon. These impurities can introduce effects on device or integrated circuit performance, including effects on device leakage current, capacitance of junctions, etc.

One way to improve device performance and to minimize the deleterious effects attributed to the bulk semiconductor material (e.g., bulk silicon material) is by separating the device layer from the bulk. One popular approach is the introduction of an insulating layer such as sapphire or silicon dioxide (e.g., SiO₂) over the surface of a wafer then forming a thin film of sapphire single crystal semiconductor material (e.g., single crystal silicon material) over the insulating layer (e.g., an epitaxial layer of, for example, silicon formed on top of the oxide). One common terminology given to such a structure is a sapphire on silicon (SOS) or silicon on insulator (SOI) structure. An SOI structure isolates the device layer from the bulk semiconductor by forming a thin layer of silicon, on the order of 0.05 to 0.2 micron thick silicon layer over a similarly thick layer of SiO₂.

One method of forming an SOI is referred to as a SIMOX process. In this process, the top layer of a wafer is subjected to a large dosage oxygen implant. A subsequent substrate anneal causes the implanted oxygen to convert to a sub-surface, stoichiometric SiO₂ from the bulk outward until all the oxygen is consumed. The process is called Oswald ripening and the thickness and position of the SiO₂ layer depends, inter alia, on the dose of the implanted oxygen and implantation energy, respectively.

A second method of forming an SOI structure is through a bonded wafer approach. In one such approach, two wafers are separately fabricated. On the first wafer, a thin layer of SiO₂ is thermally grown. The second wafer is implanted with a high dosage of hydrogen (H₂). The implanted hydrogen produces a damage layer in the bulk of the wafer. The wafers are then bonded together, with the second wafer bonded over the SiO₂ layer of the first wafer. The bonded structure is subjected to an anneal and then sheared at the damage layer to form the SOI structure.

In both the SIMOX process and the bonded wafer process, the process to form the SOI structure can be time consuming. What is needed is an alternative approach of forming an SOI structure.

### SUMMARY

A method is disclosed. In one aspect, the method includes introducing over a wafer a material having a crystalline form. In this material, a crystal (e.g., crystallite) is identified of a desired lattice orientation. The remaining material is then configured to the lattice orientation of the identified crystal.

The method finds use in the formation of SOI and SOS structures in that a semiconductor material such as a silicon material may be introduced in a polycrystalline form over an insulator such as SiO₂ or sapphire and a desired crystal orientation may be identified in the polycrystalline material and the remaining material configured to the lattice orientation of the identified crystal. Thus, a single crystal layer (e.g., epitaxial layer) of silicon may be formed over the SiO₂ or sapphire layer.

In one aspect, the method identifies, e.g., by x-ray difraction, a crystal in a material such as semiconductor material having a desired lattice orientation, e.g., Si{100}, and the remaining crystals of the material are configured to the lattice orientation of the crystal. In another aspect, the crystal is identified in an area corresponding with a center axis of the wafer and the remaining crystals of the material are configured to the orientation of the identified crystal by transforming the remaining crystals from a crystalline form to an amorphous form and re-crystallizing the amorphisized polycrystalline material to a single crystalline material throughout the layer over the wafer. One way this is accomplished is by exposing the crystals desired to be configured to a particular lattice orientation to a high energy light source, such as a laser, and re-crystallizing through epitaxial re-growth. The light source transforms the material from a crystalline form to an amorphous form, for example, by melting. The wafer is rotated in concentric revolutions about an axis of the wafer to expose additional crystals to the laser light. As the melted crystals cool, they re-crystallize to the orientation of the identified crystal.

A machine-readable medium comprising executable program instructions is also disclosed. The instructions when executed cause a digital processing system to perform a method including identifying a crystal of a desired lattice orientation in a material introduced over a wafer, the material having a polycrystalline form and configuring the material to a lattice orientation of the identified crystal. A system is also disclosed. The system includes a chamber, a laser light source coupled to the chamber and configured to direct a laser light into the chamber, and a processor comprising a machine-readable medium with executable program instructions to identify a crystal of a desired lattice orientation in a material introduced over a wafer, the material having a polycrystalline form over a wafer and configuring the material to a lattice orientation of the identified crystal.

Additional features, embodiments, and benefits will be evident in view of the figures and detailed description presented herein.

### BRIEF DESCRIPTION OF THE DRAWINGS

The features, aspects, and advantages of the invention will become more thoroughly apparent from the following detailed description, appended claims, and accompanying drawings in which:

FIG. 1 is a schematic, cross-sectional side view of a system according to the invention including a chamber for fabricating a wafer according to the invention.

FIG. 2 illustrates a schematic planar top view of a wafer having a material of a crystalline form of random orientation formed over the illustrated surface of a wafer and a crystal in the material of a desired lattice orientation according to an embodiment of the invention.

FIG. 3 shows the wafer of FIG. 2 with concentric circles formed over the surface of the wafer by a high energy light in accordance with an embodiment of the invention.

FIG. 4 shows a schematic side view of the structure of FIG. 2 after configuring the crystalline material to the lattice orientation of the identified crystal in accordance with an embodiment of the invention.

### DETAILED DESCRIPTION

A method relating to configuring a material having a crystalline form over a wafer to a desired lattice orientation of a crystal of the material. One application of the method is in the formation of an SOI or SOS structure. In this manner, a semiconductor material such as silicon may be introduced over an insulating layer such as SiO₂ or sapphire on a wafer. The semiconductor material such as silicon may be introduced in polycrystalline form as a thin film made up of many crystallites (i.e., crystals). A crystal of the semiconductor material having a desired lattice orientation is identified and the remaining crystals are configured to adapt to the orientation of the identified crystal. In this manner, a single crystal layer of, for example, silicon may be fabricated over an insulating material to form the SOI or SOS structure. In this respect, the invention offers a method of efficiently forming SOI or SOS structures.

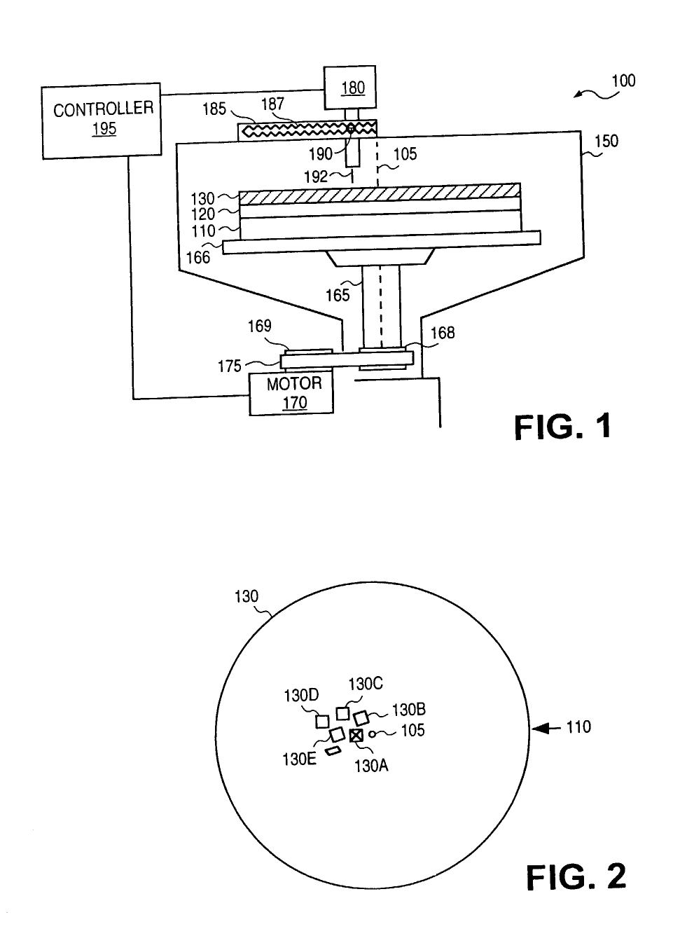

A system for configuring a material introduced over a wafer to a desired orientation is also disclosed. FIG. 1 illustrates an embodiment of such a system. FIG. 1 shows a cross-sectional side view of a wafer processing chamber 150 included as part of system 100. Disposed within chamber 150 is stage 160 that supports a wafer, such as an eight-inch diameter, essentially cylindrical wafer having a thickness on the order of 600-750 microns. In this illustration, wafer 110 is seated on a superior (e.g., top) surface of stage 160 inside processing chamber 150. Stage 160 is supported in chamber 150 by shaft 165 extending through a base of processing chamber 150. The base of shaft 165 is coupled to shaft pulley ring 168. Motor 170, in this instance, outside processing chamber 150, is coupled to pulley ring 168 to rotate shaft 165 and stage 160. Motor pulley ring 169 is coupled to a shaft of motor 170 and motor pulley ring 169 is aligned in the same plane with shaft pulley ring 168. Belt 175 extends around shaft pulley ring 168 and motor pulley ring 169 to rotate shaft 165 and stage 160 in response to a rotation of motor 170 through, for example, a gear head assembly. Details about the gear-head assembly and rotation of motor 170 and motor pulley ring 169 and shaft pulley ring 168 are not provided so as not to obscure the invention. Similarly, additional components, such as components to maintain, for example, where necessary a desired temperature or pressure within processing chamber 150 are not described as such are unnecessary for an understanding of the invention.

Referring to wafer 110, seated on a superior surface of stage 160 in system 100 of FIG. 1, wafer 110 includes a thin film of the insulating material 120 formed on an exposed surface. Insulating material 120 is, for example, SiO₂ grown through a thermal growth process to a thickness of approximately 0.05-0.2 micron thickness to act as the insulating material for an SOI structure. The growth of insulating material 120 of SiO₂ follows conventional processing techniques. A sapphire material may alternatively be grown for an SOS structure as can other materials as desired.

Introduced over insulating material 120 is a thin layer of silicon material 130 in polycrystalline form to a thickness of approximately, in this embodiment, 0.05-0.2 microns. Silicon material 130 may be introduced by way of a plasma enhanced chemical vapor deposition (PECVD) process as known in the art. Silicon material 130 is, in this embodiment, of polycrystalline form and thus is composed of a myriad of small single crystallites, i.e., crystals of random orientation. In one embodiment, the chamber temperature is optimized during silicon introduction to produce large silicon crystallites. Although a silicon material is described, it is to be appreciated that other semiconductor materials, or other crystalline materials for that matter, may be alternatively introduced depending on the desired process. It is also to be appreciated that the introduction of silicon material 130 may occur in a chamber other than processing chamber 150 and then wafer 110 may be transferred to processing chamber 150 for further processing.

FIG. 2 shows a top surface of wafer 110 having silicon material 130 introduced over the surface. As illustrated in FIG. 2, silicon material 130 is made up of a myriad of single crystals or crystallites of random orientation. These different orientations are illustrated schematically as 130A, 130B, 130C, 130D, and 130E and representatively described as {100}-, {110}, and {111}-orientation, although other orientations are likely also present. In the representation shown in FIG. 2, the different orientations are represented adjacent an area corresponding with central axis 105 of wafer 110.

In one embodiment, the crystalline structure of silicon material 130 is analyzed in situ at an area adjacent central axis 105 for the orientation of crystals adjacent the axis. Such analysis may be conducted through, for example, x-ray or electron beam diffraction techniques so that the orientation of the crystals may be identified. To facilitate the identification of the orientation of crystals in silicon material 130, the structure may be subjected to a heat treatment (e.g., on the order of 300 to 700° C. for up to 30 minutes) to grow larger crystals. The analysis permits the selection of a crystal of a desired lattice orientation in silicon material 130 adjacent central axis 105. In this case, crystal 130A ({110}) is selected as having the desired crystal orientation. Due to the myriad of crystals present in a polycrystalline layer or film, it is appreciated that a crystal having the desired orientation can be identified near central axis 105. Where such crystal is not present adjacent central axis 105, the area for the search may be expanded as necessary.

Returning to FIG. 1, one way of configuring the crystals of silicon material 130 to the lattice orientation of crystal 130A is by melting the crystals and re-growing such crystals with the orientation of crystal 130A. It is generally recognized that an amorphourized crystal material will seek reorder in crystalline form as a lower energy state and similarly will have an affinity for the crystal orientation of adjacent crystals in the material. The method described herein capitalizes on this property of crystal material to form a single crystal film of a desired lattice orientation.

FIG. 1 shows high energy beam source 180 coupled to a top surface of processing chamber 150. High energy beam source 180 is, for example, an excimer laser. High energy beam source 180 directs high energy light 192 onto a top surface of wafer 110 inside processing chamber 150. In one embodiment, high energy beam source 180 produces beam 192 of laser light having a beam diameter similar or smaller in size to that of a crystal diameter of silicon material 130. A representative beam diameter for such an embodiment is one to three microns. In this manner, beam 192 from high energy beam source 180 can be directed at the individual crystals of silicon material 130. In one example, high energy light source 180 is an excimer laser that applies light beam 192 in 10 nanosecond pulses to melt the crystals of silicon material 130.

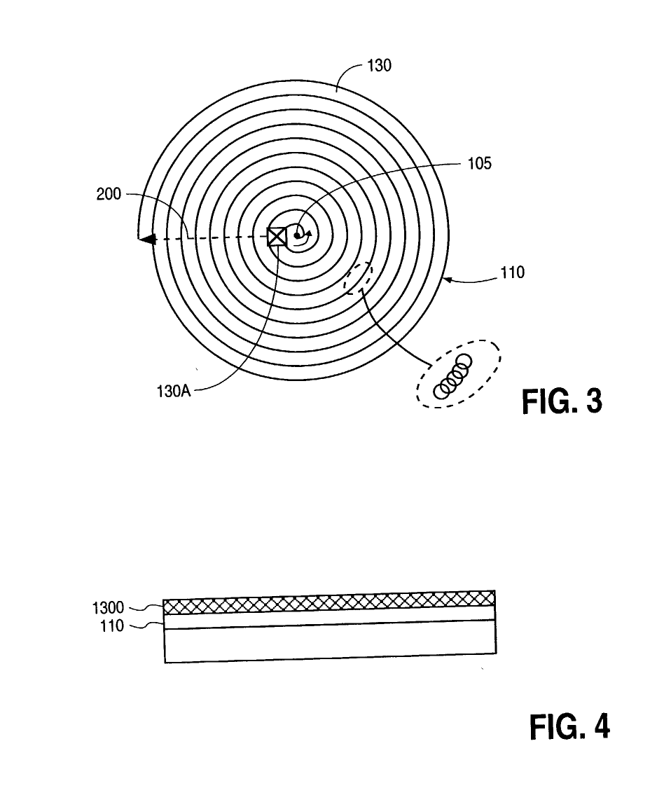

Referring to FIG. 1, system 100 includes motor 170 to rotate shaft 155 and stage 160 and consequently wafer 110. The rotation allows beam 192 to be directed in revolutions about central axis 105 of wafer 110. FIG. 3 shows a series of revolutions about central axis 105 of wafer 110, starting adjacent identified crystal 130A and moving outward in circles or revolutions of increasingly greater radius. Beam 192 is emitted from high energy beam source 180 in the form of pulses, such as laser pulses, directed at crystals that make up silicon material 130 to melt such crystals in a counter-clockwise direction.

FIG. 3 also shows, in an insert, a magnified view of a portion of the pulse pattern of light beam 192. The insert shows that wafer 110 is rotated, in this example, at a speed whereby the individual pulses of light 192 overlap one another. Such overlap insures that each crystal of silicon material 130 is melted as wafer 110 is rotated. It is to be appreciated that, given a sufficient intensity of light and a sufficient pulse time, such an overlap is not necessary.

Referring to FIG. 1, one way of forming concentric revolutions about wafer 110, each revolution having a different radius than its predecessor, is by controlling the location of light beam 192 from high energy light source 180 as wafer 110 is rotated. One way this is accomplished is through mounting high energy light source 180 on radial position track 185. Radial transfer arm 185 is mounted on processing chamber 150 and provides a track for movement of high energy light source 180 in a radial direction over wafer 110.

FIG. 3 shows the radial movement 200 of high energy light source 180 and light beam 192 in a radial direction across the top surface of wafer 110. In one example, wafer 110 is rotated in continuous revolutions allowing a movement of high energy light source 180 along a radius to expose the surface of wafer 110 associated with the circumference of each revolution to beam 192 from high energy light source 180. At the completion of each revolution, high energy light source 180 is adjusted radially (e.g., from a first radius to a second greater radius) and a subsequent revolution is traced by high energy light source 180. In one example, radial transfer arm 185 comprises track 187 extending the length of a radius of a wafer on stage 166. Pin 190 coupled to and extending laterally from light pipe 191 of high energy light source 180, is positioned in track 187. High energy light source 180 is moved radially by positioning pin 190 within track 187. Such positioning may be done manually or more preferably electrically and with the aid of motor assembly (not shown). Such motor assembly may be controlled by controller 195. Information about the location of pin 190 may also be stored and monitored by controller 195. Processor or controller 195 controls the radial movement of high energy light source 180 in radial transfer arm 185.

FIG. 1 illustrates system controller or processor 195 coupled to a high energy light source 180 and motor 170. Controller 195 is configured to monitor the position of high energy light source 180 and control the power supplied to motor 170, and thus the revolution velocity based, for example, on an algorithm that determines a circumference of each revolution and the pulse duration of high energy light source 180 and adjusts motor 170 accordingly. Controller 195 may also be configured to control the mixture and flow of film forming agents to chamber 150. In an LPCVD reaction process, the controller may further be coupled to a pressure indicator that measures the pressure in the chamber as well as a vacuum source to adjust the pressure in the chamber.

Controller or processor 195 is supplied with software instruction logic that is a computer program stored in a computer readable medium such as memory in the system controller. The memory is, for example, a portion of a hard disk drive. The controller may also be coupled to a user interface that allows an operator to enter the process parameters, such as the desired pulse duration, the light pulse diameter, and the desired number of revolutions to melt substantially all the grains of silicon material 130. Alternatively, certain values may be calculated by algorithm(s) stored in controller 195.

As noted above, controller 195 may also control the positioning of high energy light source 180. In one example, controller stores information about the location of pin 190 and extrapolates, for this information, information about the position of beam 192 over wafer 110. Controller 195 also stores information about beam diameter and wafer diameter. An algorithm supplied to controller 195 determines the number of radial positions necessary for all the material on wafer 110 to be exposed to beam 192 (wafer radius from crystal 130A divided by beam 192 diameter). With this information, controller 195 positions high energy light source 180. A signal from motor 170 or a sensor coupled to motor pulley ring 169 or shaft pulley ring 168 alerts controller 195 to a complete revolution and controller 195 in turn adjusts high energy light source 180.

FIG. 4 shows the structure of FIG. 2 after the transformation of silicon material 130 to single crystal material 1300 using the process described above. In one example, silicon material 1300 is an epitaxial film of single crystal silicon, with substantially all of the crystals configured with an orientation of crystal 130A-{100}. According to the invention, an efficient method of orienting a material on a substrate is illustrated. Since the process relies on directly transforming discrete crystals or small amounts of crystals at any one time, the process can more accurately transform such crystals to a desired orientation than prior art methods that rely on thermal processing to transform all the material at once. Further, since the process described reorients the film on a surface, the general characteristics of the film, such as film thickness may more accurately be characterized than prior art processes that, for example, rely on wafer shear techniques to produce the film.

In the preceding detailed description, the invention is described with reference to specific embodiments thereof. It will, however, be evident that various modifications and changes may be made thereto without departing from the broader spirit and scope of the invention as set forth in the claims. The specification and drawings are, accordingly, to be regarded in an illustrative rather than a restrictive sense.

What is claimed is:

1. A method comprising:
introducing over a wafer a material having a crystalline form;
identifying a crystal in the material of a desired lattice orientation; and
configuring the material to-the lattice orientation of the crystal.

2. The method of claim 1, wherein configuring the material comprises, in sequence:
transforming the material to an amorphous form; and
re-crystallizing the material in the amorphous form.

3. The method of claim 2, wherein transforming the material to an amorphous form comprises melting the material.

4. The method of claim 3, wherein melting the material comprises contacting the material at discrete locations with a laser light.

5. The method of claim 4, further comprising rotating the wafer about an axis to melt the material in revolutions about the axis.

6. The method of claim 5, wherein identifying the crystal comprises identifying a crystal in an area corresponding with the center of the wafer and the axis of rotation is the center of the wafer.

7. A method comprising:
introducing over a wafer a semiconductor material having a polycrystalline form;
identifying a crystal in the semiconductor material of a desired lattice orientation in an area corresponding with a center axis of the wafer; and
configuring the non-identified semiconductor material to the lattice orientation of the crystal.

8. The method of claim 7, wherein configuring the non-identified semiconductor material comprises:
a) contacting the semiconductor material with a laser light at a first discrete point;
b) melting the contacted semiconductor material with the laser light; and
c) rotating the wafer about the center axis and repeating the sequence of a) and b) about a revolution.

9. The method of claim 8, further comprising, with the completion of each revolution, moving the laser radially in reference to the wafer to define a subsequent revolution.

10. A machine readable medium comprising executable program instructions that when executed cause a digital processing system to perform a method comprising:
identifying a crystal of a desired lattice orientation in a material introduced over a wafer, the material having a crystalline form; and
configuring the material to a lattice orientation of the identified crystal.

11. The medium of claim 10, wherein configuring the material comprises, in sequence, transforming the material to an amorphous form, and re-crystallizing the material in the amorphous form.

12. The medium of claim 11, wherein transforming the material to an amorphous form comprises melting the material.

13. The medium of claim 12, wherein melting the material comprises contacting the material at discrete locations with a laser light.

14. The medium of claim 13, wherein the method further comprises rotating the wafer about an axis to melt the material in revolutions about the axis.

15. The medium of claim 14, wherein identifying the crystal comprises identifying a crystal in an area corresponding with the center of the wafer and the axis of rotation is the center of the wafer.

16. The medium of claim 15, wherein the method further comprises, with the completion of each revolution, moving the laser radially in reference to the wafer to define a subsequent revolution.

17. A system for growing a film on a substrate comprising:
a chamber;
a laser light source coupled to the chamber and configured to direct a laser light into the chamber; and
a processor coupled to the chamber comprising a machine readable medium comprising executable program instructions that when executed cause the processor to perform a method comprising:
identifying a crystal of a desired lattice orientation in a crystalline material introduced over a wafer; and
configuring the material to a lattice orientation of the identified crystal.

18. The system of claim 17, wherein configuring the material comprises, in sequence, transforming the material to an amorphous form, and re-crystallizing the material in the amorphous form.

19. The system of claim 18, wherein transforming the material comprises contacting the material at discrete locations with a laser light.

20. The system of claim 19, wherein the method further comprises:
rotating the wafer about an axis to melt the material in revolutions about the axis; and
with the completion of each revolution, moving the laser radially in reference to the wafer to define a subsequent revolution.
